(19) United States
(12) Patent Application Publication
(10) Pub. No.: US 2019/0309412 A1
(43) Pub. Date: Oct. 10, 2019

(54) Methods For Low Temperature ALD Of Metal Oxides

(71) Applicant: Applied Materials, Inc., Santa Clara, CA (US)

(72) Inventors: Bhaskar Jyoti Bhuyan, San Jose, CA (US); Mark Saly, Santa Clara, CA (US); Cong Trinh, Santa Clara, CA (US); Mihaela Balseanu, Sunnyvale, CA (US); Lakmal C. Kalutarage, San Jose, CA (US)

(21) Appl. No.: 16/376,176

(22) Filed: Apr. 5, 2019

Related U.S. Application Data
(60) Provisional application No. 62/653,534, filed on Apr. 5, 2018.

(51) Int. Cl. C23C 16/40; C23C 16/455

(52) U.S. Cl. CPC C23C 16/403; C23C 16/45534; C23C 16/45553

(57) ABSTRACT

Methods for depositing metal oxide layers on metal surfaces are described. The methods include exposing a substrate to separate doses of a metal precursor, which does not contain metal-oxygen bonds, and a modified alcohol with an electron withdrawing group positioned relative to a beta carbon so as to increase the acidity of a beta hydrogen attached to the beta carbon. These methods do not oxidize the underlying metal layer and are able to be performed at lower temperatures than processes performed with water or without modified alcohols.

### CROSS-REFERENCE TO RELATED APPLICATIONS

This application claims priority to U.S. Provisional Application No. 62/653,534, filed Apr. 5, 2018, the entire disclosure of which is hereby incorporated by reference herein.

### TECHNICAL FIELD

Embodiments of the disclosure relate to methods of depositing thin films. In particular, embodiments of the disclosure relate to methods for depositing metal oxides at low temperatures.

### BACKGROUND

Thin films are widely used in semiconductor manufacturing for many processes. For example, thin films of metal oxides (e.g., aluminum oxide) are often used in patterning processes as spacer materials and etch stop layers. These materials allow for smaller device dimensions without employing more expensive EUV lithography technologies.

Common techniques for depositing metal oxides on substrate surfaces often involve oxidizing a portion of the substrate surface. The oxidation process, especially on metal surfaces, can be detrimental to device performance.

In specific, the use of water as an atomic layer deposition (ALD) reactant can lead to surface oxidation. Additionally, water is relatively adhesive to chamber walls and the use of water as a reactant decreases throughput due to the requirement for longer purge times.

The use of alcohols as oxidizing reactants ameliorates concerns related to surface oxidation and low throughput. However, deposition temperatures must be higher than similar water-based processes due to a higher activation barrier.

Therefore, there is a need in the art for methods of the atomic layer deposition of metal oxides capable of being performed at lower temperatures without surface oxidation.

### SUMMARY

One or more embodiments of the disclosure are directed to deposition methods comprising providing a substrate with a first metal surface. The substrate is separately exposed to a second metal precursor and an alcohol to form a second metal oxide layer on the first metal surface. The second metal precursor comprises substantially no metal-oxygen bonds. The alcohol comprises an electron-withdrawing group positioned relative to a beta carbon of the alcohol to increase acidity of a beta hydrogen attached to the beta carbon.

Additional embodiments of the disclosure are directed to deposition methods comprising providing a substrate with a first metal surface. The first metal consists essentially of cobalt. The substrate is separately exposed to trimethyl aluminum and 3,3,3-trifluoropropanol to form an aluminum oxide layer on the first metal surface.

Further embodiments of the disclosure are directed to a deposition method comprising providing a substrate with a first metal surface. The substrate is separately exposed to a second metal precursor and a first alcohol. The second metal precursor comprises substantially no metal-oxygen bonds. The first alcohol comprises an electron-withdrawing group positioned relative to a beta carbon of the first alcohol to increase acidity of a beta hydrogen attached to the beta carbon of the first alcohol. The substrate is separately exposed to a third metal precursor and a second alcohol to form a mixed metal oxide layer on the first metal surface. The third metal precursor comprises substantially no metal-oxygen bonds. The second alcohol comprises an electron-withdrawing group positioned relative to a beta carbon of the second alcohol to increase acidity of a beta hydrogen attached to the beta carbon of the second alcohol. The mixed metal oxide comprises the second metal and the third metal. The first metal, the second metal and the third metal are each different metals.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

Embodiments of the disclosure provide methods to deposit metal oxide layers onto metal surfaces with substantially no oxidation of the metal surface. As used in this regard, “substantially no oxidation” means that the surface contains less than 5%, 2%, 1% or 0.5% of oxygen based on a count of surface atoms. Without being bound by theory, oxidation of the metal surface may increase resistivity of the underlying metal material and lead to an increased rate of device failure. Embodiments of this disclosure advantageously provide for the deposition of a second metal oxide layer without oxidation of the first metal surface.

Embodiments of the disclosure provide methods to deposit metal oxide layers onto metal surfaces at lower temperatures. As used in this regard, “lower temperatures” are evaluated relative to a deposition process which does not use an alcohol as described in this disclosure. Without being bound by theory, the modified alcohols of this disclosure promote a beta hydride elimination reaction and lower the activation barrier of the thermal rearrangement allowing the methods to be performed at lower temperatures. Embodiments of this disclosure advantageously provide for the deposition of a metal oxide layer at relatively low temperatures.

For example, a method to deposit aluminum oxide on cobalt which utilizes trimethyl aluminum and water produces significant amounts of cobalt oxide between the cobalt layer and the aluminum oxide layer. In contrast, a method to deposit aluminum oxide on cobalt which utilizes trimethyl aluminum and alcohol deposits a similar aluminum oxide layer without producing a cobalt oxide layer between the cobalt layer and aluminum oxide layer.

Additionally, for example, a method to deposit aluminum oxide on cobalt which utilizes trimethyl aluminum and isopropyl alcohol are generally performed at temperatures at or above 350° C. In contrast, the disclosed methods deposit a similar aluminum oxide layer utilizing a modified alcohol which allows for deposition at a lower temperature.

A “substrate surface”, as used herein, refers to any portion of a substrate or portion of a material surface formed on a substrate upon which film processing is performed. For example, a substrate surface on which processing can be performed include materials such as silicon, silicon oxide, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present invention, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface. Substrates may have various dimensions, such as 200 mm or 300 mm diameter wafers, as well as, rectangular or square panes. In some embodiments, the substrate comprises a rigid discrete material.

“Atomic layer deposition” or “cyclical deposition” as used herein refers to the sequential exposure of two or more reactive compounds to deposit a layer of material on a substrate surface. As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction). The substrate, or portion of the substrate, is exposed sequentially to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

According to one or more embodiments, the method uses an atomic layer deposition (ALD) process. In such embodiments, the substrate surface is exposed to the precursors (or reactive gases) separately or substantially separately. As used herein, “separately” means that the metal precursor and the alcohol are separated temporally, spatially or both. As used herein throughout the specification, “substantially separately”, as it relates to temporal separation, means that a majority of the duration of a precursor exposure does not overlap with the exposure to a co-reactant, although there may be some overlap. As used herein throughout the specification, “substantially separately”, as it relates to spatial separation, means that a majority of the exposure area of a precursor exposure does not overlap with the exposure area of a co-reactant, although there may be some overlap.

As used in this specification and the appended claims, the terms “precursor”, “reactant”, “reactive gas” and the like are used interchangeably to refer to any gaseous species that can react with the substrate surface, or a species present on the substrate surface.

In one or more embodiments, the method is performed using an atomic layer deposition (ALD) process. An ALD process is a self-limiting process where a single layer of material is deposited using a binary (or higher order) reaction. An individual ALD reaction is theoretically self-limiting continuing until all available active sites on the substrate surface have been reacted. ALD processes can be performed by time-domain ALD or spatial ALD processes.

In a time-domain ALD process, the processing chamber and substrate are exposed to a single reactive gas at any given time. In an exemplary time-domain process, the processing chamber might be filled with a metal precursor for a time to allow the metal precursor to fully react with the available sites on the substrate. The processing chamber can then be purged of the precursor before flowing a second reactive gas into the processing chamber and allowing the second reactive gas to fully react with the substrate surface or material on the substrate surface. The time-domain process minimizes the mixing of reactive gases by ensuring that only one reactive gas is present in the processing chamber at any given time. At the beginning of any reactive gas exposure, there is a delay in which the concentration of the reactive species goes from zero to the final predetermined pressure. Similarly, there is a delay in purging all of the reactive species from the process chamber.

In a spatial ALD process, the substrate is moved between different process regions within a single processing chamber. Each of the individual process regions is separated from adjacent process regions by a gas curtain. The gas curtain helps prevent mixing of the reactive gases to minimize any gas phase reactions. Movement of the substrate through the different process regions allows the substrate to be sequentially exposed to the different reactive gases while preventing gas phase reactions.

In some embodiments, a substrate containing a first metal layer has a first metal surface. The first metal may be any suitable metal. Ideally, the first metal surface consists essentially of the first metal. In practice, the first metal surface may additionally comprise contaminants or other films on its surface which comprise elements other than the first metal.

In some embodiments, the first metal comprises one or more of cobalt, copper, nickel, ruthenium, tungsten, or platinum. In some embodiments, the first metal is a pure metal comprising a single metal species. As used in this manner, a “pure” metal refers to a film having a composition greater than or equal to about 95%, 98%, 99% or 99.5% of the stated metal, on an atomic basis. In some embodiments, the first metal is a metal alloy and comprises multiple metal species. In some embodiments, the first metal consists essentially of cobalt, copper, nickel, ruthenium, tungsten, or platinum. In some embodiments, the first metal consists essentially of cobalt. In some embodiments, the first metal consists essentially of copper. As used in this regard, “consists essentially of” means that the stated material is greater than or equal to about 95%, 98%, 99% or 99.5% of the stated species.

The substrate is provided for processing by the disclosed methods. As used in this regard, the term “provided” means that the substrate is placed into a position or environment for further processing. The substrate is exposed to a second metal precursor and an alcohol to form a second metal oxide layer on the first metal surface. In some embodiments, the substrate is exposed to the second metal precursor and the alcohol separately.

The second metal precursor comprises a second metal and one or more ligands. The second metal may be any suitable metal from which a metal oxide may be formed. In some embodiments, the second metal comprises one or more of aluminum, hafnium, zirconium, nickel, zinc, tantalum or titanium. In some embodiments, the second metal consists essentially of aluminum, hafnium, zirconium, nickel, zinc, tantalum or titanium. In some embodiments, the second metal consists essentially of aluminum.

A ligand of the second metal precursor may be any suitable ligand. In some embodiments, the second metal precursor contains substantially no metal-oxygen bonds. As used in this regard, “contains substantially no metal-oxygen bonds” means that the second metal precursor has metal-ligand bonds which contain fewer than 2%, 1% or 0.5% of metal-oxygen bonds as measured by total metal-ligand bond count. As used in this disclosure, a description of a ligand is primarily made by the element which attaches to the metal center of the second metal precursor. Accordingly, a carbo ligand would exhibit a metal-carbon bond; an amino ligand would exhibit a metal-nitrogen bond; and a halide ligand would exhibit a metal-halogen bond.

In some embodiments, the second metal precursor comprises at least one carbo ligand. In some embodiments, the second metal precursor comprises only carbo ligands. In embodiments where at least one carbo ligand is present, each carbo ligand independently contains from 1 to 6 carbon atoms. In some embodiments where the second metal precursor comprises at least one carbo ligand, the disclosed methods provide a second metal oxide layer which contains substantially no carbon.

In some embodiments, the second metal precursor consists essentially of trimethyl aluminum (TMA). In some embodiments, the second metal precursor consists essentially of triethyl aluminum (TEA).

In some embodiments, the second metal precursor comprises at least one amino ligand. In some embodiments, the second metal precursor comprises only amino ligands. In some embodiments, the second metal precursor comprises only amino ligands and each amido ligand is the same ligand. In some embodiments, the second metal precursor consists essentially of tris(dimethylamido)aluminum (TDMA). In some embodiments, the second metal precursor consists essentially of tris(diethylamido)aluminum (TDEA). In some embodiments, the second metal precursor consists essentially of tris(ethylmethylamido)aluminum (TEMA).

In some embodiments, the second metal precursor comprises at least one halide ligand. In some embodiments, the second metal precursor comprises only halide ligands. In some embodiments, the second metal precursor consists essentially of aluminum fluoride (AlF₃). In some embodiments, the second metal precursor consists essentially of aluminum chloride (AlCl₃).

The alcohol comprises at least one beta hydrogen. A beta hydrogen is a hydrogen bonded to the second carbon from the hydroxyl group (the beta carbon). The alcohol comprises an electron-withdrawing group positioned relative to the beta carbon to increase the acidity of a beta hydrogen attached to the beta carbon.

Suitable electron withdrawing groups include, but are not limited to, halides (including dihalide and/or trihalide groups), ketones, alkenes, alkynes, phenyls, ethers, esters, nitro groups, and cyano groups. In some embodiments, the electron withdrawing group is selected from halide, ketone, ether, ester, nitro, and cyano groups. In some embodiments, the electron withdrawing group is selected from alkenes, alkynes and phenyl groups. In some embodiments, the electron withdrawing group is selected from alkynes and phenyl groups.

Exemplary alcohols which comprise a halide group include 1-chloro-2-propanol. Exemplary alcohols which comprise a ketone group include 4-hydroxy-2-butanone, 4-hydroxy-2-pentanone and 4-hydroxy-4-methyl-2-pentanone. Exemplary alcohols which comprise an alkene group include 3-buten-2-ol, 3-methyl-2-buten-2-ol, 4-penten-2-ol and 1,6-heptadien-4-ol. Exemplary alcohols which comprise a phenyl group include 1-phenyl-2-propanol. Exemplary alcohols which comprise an ester include 2-methoxyethanol. Exemplary alcohols which comprise a trihalide group include 4,4,4-trifluoro-2-butanol.

In some embodiments, the alcohol is a primary alcohol. In some embodiments, the alcohol is a secondary alcohol. In some embodiments, the alcohol is a tertiary alcohol. In some embodiments, the alcohol comprises more than one hydroxyl group. In some embodiments, the alcohol comprises beta hydrogens which are substantially unaffected by an electron-withdrawing group. In some embodiments, the alcohol comprises more than one electron-withdrawing group which increases the acidity of the same beta hydrogen.

While a substrate is processed according to embodiments of this disclosure, several conditions may be controlled. These conditions include, but are not limited to substrate temperature, flow rate, pulse duration and/or temperature of the second metal precursor and/or the alcohol, and the pressure of the processing environment.

The temperature of the substrate during deposition can be any suitable temperature depending on, for example, the precursor(s) being used. During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

In some embodiments, the substrate temperature is maintained at a temperature less than or equal to about 600° C., or less than or equal to about 550° C., or less than or equal to about 500° C., or less than or equal to about 450° C., or less than or equal to about 400° C., or less than or equal to about 350° C., or less than or equal to about 325° C., or less than or equal to about 300° C., or less than or equal to about 250° C., or less than or equal to about 200° C., or less than or equal to about 150° C., or less than or equal to about 100° C., or less than or equal to about 50° C., or less than or equal to about 25° C. In some embodiments, the substrate temperature is maintained at a temperature of about 300° C.

Without being bound by theory, it is believed that the incorporation of the electron withdrawing group(s) in the alcohol of the present disclosure lowers the activation barrier of the thermal rearrangement reaction necessary for forming the metal oxide film. Accordingly, the methods of the present disclosure may be performed at lower temperatures than similar methods performed using alcohols without electron withdrawing groups present.

For example, the reaction of TMA with isopropyl alcohol is typically performed at greater than 350° C. A similar method performed using TMA and 4-hydroxy-2-pentanone is expected to be successful at a temperature less than 350° C.

A “pulse” or “dose” as used herein is intended to refer to a quantity of a source gas that is intermittently or non-continuously introduced into the process chamber. The quantity of a particular compound within each pulse may vary over time, depending on the duration of the pulse. A particular process gas may include a single compound or a mixture/combination of two or more compounds, for example, the process gases described below.

The durations for each pulse/dose are variable and may be adjusted to accommodate, for example, the volume capacity of the processing chamber as well as the capabilities of a vacuum system coupled thereto. Additionally, the dose time of a process gas may vary according to the flow rate of the process gas, the temperature of the process gas, the type of control valve, the type of process chamber employed, as well as the ability of the components of the process gas to adsorb onto the substrate surface. Dose times may also vary based upon the type of layer being formed and the geometry of the device being formed. A dose time should be long enough to provide a volume of compound sufficient to adsorb/chemisorb onto substantially the entire surface of the substrate and form a layer of a process gas component thereon.

The reactants (e.g., the second metal precursor and the alcohol) may be provided in one or more pulses or continuously. The flow rate of the reactants can be any suitable flow rate including, but not limited to, flow rates is in the range of about 1 to about 5000 sccm, or in the range of about 2 to about 4000 sccm, or in the range of about 3 to about 3000 sccm or in the range of about 5 to about 2000 sccm. The reactants can be provided at any suitable pressure including, but not limited to, a pressure in the range of about 5 mTorr to about 25 Torr, or in the range of about 100 mTorr to about 20 Torr, or in the range of about 5 Torr to about 20 Torr, or in the range of about 50 mTorr to about 2000 mTorr, or in the range of about 100 mTorr to about 1000 mTorr, or in the range of about 200 mTorr to about 500 mTorr.

The period of time that the substrate is exposed to each reactant may be any suitable amount of time necessary to allow the reactant to form an adequate nucleation layer atop the substrate surface. For example, the reactants may be flowed into the process chamber for a period of about 0.1 seconds to about 90 seconds. In some time-domain ALD processes, the reactants are exposed the substrate surface for a time in the range of about 0.1 sec to about 90 sec, or in the range of about 0.5 sec to about 60 sec, or in the range of about 1 sec to about 30 sec, or in the range of about 2 sec to about 25 sec, or in the range of about 3 sec to about 20 sec, or in the range of about 4 sec to about 15 sec, or in the range of about 5 sec to about 10 sec.

In some embodiments, an inert gas may additionally be provided to the process chamber at the same time as the reactants. The inert gas may be mixed with the reactant (e.g., as a diluent gas) or separately and can be pulsed or of a constant flow. In some embodiments, the inert gas is flowed into the processing chamber at a constant flow in the range of about 1 to about 10000 sccm. The inert gas may be any inert gas, for example, such as argon, helium, neon, combinations thereof, or the like. In one or more embodiments, the reactants are mixed with argon prior to flowing into the process chamber.

In some embodiments, the process chamber (especially in time-domain ALD) may be purged using an inert gas. (This may not be needed in spatial ALD processes as there is a gas curtain separating the reactive gases.) The inert gas may be any inert gas, for example, such as argon, helium, neon, or the like. In some embodiments, the inert gas may be the same, or alternatively, may be different from the inert gas provided to the process chamber during the exposure of the substrate to the reactants. In embodiments where the inert gas is the same, the purge may be performed by diverting the first process gas from the process chamber, allowing the inert gas to flow through the process chamber, purging the process chamber of any excess first process gas components or reaction byproducts. In some embodiments, the inert gas may be provided at the same flow rate used in conjunction with the second metal precursor, described above, or in some embodiments, the flow rate may be increased or decreased. For example, in some embodiments, the inert gas may be provided to the process chamber at a flow rate of about 0 to about 10000 sccm to purge the process chamber. In spatial ALD, purge gas curtains are maintained between the flows of reactants and purging the process chamber may not be necessary. In some embodiments of a spatial ALD process, the process chamber or region of the process chamber may be purged with an inert gas.

The flow of inert gas may facilitate removing any excess first process gas components and/or excess reaction byproducts from the process chamber to prevent unwanted gas phase reactions of the first and second process gases.

While the generic embodiment of the processing method described herein includes only two pulses of reactive gases, it will be understood that this is merely exemplary and that additional pulses of reactive gases may be used. Similarly, the pulses of reactive gas may be repeated in whole or in part until a predetermined thickness of metal oxide film has been formed.

In some embodiments, the substrate is exposed to a second metal precursor, a first alcohol and a third metal precursor. In some embodiments, the substrate is exposed to a second metal precursor, a first alcohol, a third metal precursor and a second alcohol. These exposures may be performed in any order and repeated in whole or in part.

The third metal precursor is similar to the second metal precursor regarding the ligands attached thereto, but may comprise a different metal. The second alcohol is similar to the first alcohol in terms of having a beta hydrogen with increased acidity, but may comprise a different alcohol.

In some embodiments, the substrate is exposed to a second metal precursor, a first alcohol, a third metal precursor and a second alcohol to form a mixed metal oxide layer on the substrate. In some embodiments, the mixed metal oxide comprises the second metal and the third metal. In some embodiments, the first metal, the second metal and the third metal are each different metals.

The processing chamber pressure during deposition can be in the range of about 50 mTorr to 750 Torr, or in the range of about 100 mTorr to about 400 Torr, or in the range of about 1 Torr to about 100 Torr, or in the range of about 2 Torr to about 10 Torr.

The second metal oxide layer formed can be any suitable film. In some embodiments, the film formed is an amorphous or crystalline film comprising one or more species according to MOₓ, where the formula is representative of the atomic composition, not stoichiometric. In some embodiments, the second metal oxide is stoichiometric. In some embodiments, the second metal film has a ratio of second metal to oxygen which is greater than the stoichiometric ratio. In some embodiments, the second metal film has a ratio of second metal to oxygen which is less than the stoichiometric ratio.

Upon completion of deposition of the second metal oxide layer to a predetermined thickness, the method generally ends and the substrate can proceed for any further processing.

In atomic layer deposition type chambers, the substrate can be exposed to the first and second precursors either spatially or temporally separated processes. Temporal ALD is a traditional process in which the first precursor flows into the chamber to react with the surface. The first precursor is purged from the chamber before flowing the second precursor. In spatial ALD, both the first and second precursors are simultaneously flowed to the chamber but are separated spatially so that there is a region between the flows that prevents mixing of the precursors. In spatial ALD, the substrate is moved relative to the gas distribution plate, or vice-versa.

In embodiments, where one or more of the parts of the methods takes place in one chamber, the process may be a spatial ALD process. Although one or more of the chemistries described above may not be compatible (i.e., result in reaction other than on the substrate surface and/or deposit on the chamber), spatial separation ensures that the reagents are not exposed to each in the gas phase. For example, temporal ALD involves the purging the deposition chamber. However, in practice it is sometimes not possible to purge all of the excess reagent out of the chamber before flowing in additional regent. Therefore, any leftover reagent in the chamber may react. With spatial separation, excess reagent does not need to be purged, and cross-contamination is limited. Furthermore, a lot of time can be taken to purge a chamber, and therefore throughput can be increased by eliminating the purge step.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

What is claimed is:

1. A deposition method comprising:
providing a substrate with a first metal surface; and
exposing the substrate separately to a second metal precursor and an alcohol to form a second metal oxide layer on the first metal surface, the second metal precursor comprising substantially no metal-oxygen bonds, the alcohol comprising an electron-withdrawing group positioned relative to a beta carbon of the alcohol to increase acidity of a beta hydrogen attached to the beta carbon.

2. The method of claim 1, wherein the substrate is maintained at a temperature less than or equal to about 350° C.

3. The method of claim 1, wherein the first metal comprises one or more of cobalt, copper, nickel, ruthenium, tungsten, or platinum.

4. The method of claim 1, wherein the first metal consists essentially of cobalt.

5. The method of claim 1, wherein the first metal consists essentially of copper.

6. The method of claim 1, wherein the second metal comprises one or more of aluminum, hafnium, zirconium, nickel, zinc, tantalum or titanium.

7. The method of claim 1, wherein the second metal consists essentially of aluminum.

8. The method of claim 1, wherein the second metal precursor comprises at least one carbo ligand.

9. The method of claim 8, wherein the at least one carbo ligand contains 1 to 6 carbon atoms.

10. The method of claim 8, wherein the second metal precursor comprises only carbo ligands.

11. The method of claim 1, wherein the second metal precursor comprises at least one amino ligand.

12. The method of claim 1, wherein the second metal precursor comprises at least one halide ligand.

13. The method of claim 1, wherein the alcohol contains 2 to 10 carbon atoms.

14. The method of claim 1, wherein the alcohol is a secondary alcohol.

15. The method of claim 1, wherein the electron-withdrawing group is selected from halide, ketone, alkene, alkyne, phenyl, ether, ester, nitro, cyano or trihalide groups.

16. The method of claim 1, wherein the alcohol is selected from 4-hydroxy-2-butanone, 4-hydroxy-2-pentanone, 4-hydroxy-4-methyl-2-pentanone, 1-chloro-2-propanol, 2-methoxyethanol, 1-phenyl-2-propanol, 3-buten-2-ol, 3-methyl-2-buten-2-ol, 4-penten-2-ol, 1,6-heptadien-4-ol, 4,4,4-trifluoro-2-butanol or combinations thereof.

17. A deposition method comprising:
providing a substrate with a first metal surface, the first metal consisting essentially of cobalt; and
exposing the substrate separately to trimethyl aluminum and 4-hydroxy-2-pentanone to form an aluminum oxide layer on the first metal surface.

18. The method of claim 17, wherein the substrate is maintained at a temperature less than or equal to about 350° C.

19. A deposition method comprising:
providing a substrate with a first metal surface;
exposing the substrate separately to a second metal precursor and a first alcohol, the second metal precursor comprising substantially no metal-oxygen bonds, the first alcohol comprising an electron-withdrawing group positioned relative to a beta carbon of the first alcohol to increase acidity of a beta hydrogen attached to the beta carbon of the first alcohol; and
exposing the substrate separately to a third metal precursor and a second alcohol to form a mixed metal oxide layer on the first metal surface, the third metal precursor comprising substantially no metal-oxygen bonds, the second alcohol comprising an electron-withdrawing group positioned relative to a beta carbon of the second alcohol to increase acidity of a beta hydrogen attached to the beta carbon of the second alcohol,
wherein the mixed metal oxide comprises the second metal and the third metal, and the first metal, the second metal and the third metal are each different metals.

20. The method of claim 19, wherein the first alcohol and the second alcohol are the same alcohol.
